(19) United States
(12) Patent Application Publication
(10) Pub. No.: US 2003/0184221 A1
(43) Pub. Date: Oct. 2, 2003

(54) Light-emitting device

(76) Inventor: Masayuki Mishima, Kanagawa (JP)

Correspondence Address: BIRCH STEWART KOLASCH & BIRCH, PO BOX 747, FALLS CHURCH, VA, 22040-0747, US

(21) Appl. No.: 10/400,584

(22) Filed: Mar. 28, 2003

(30) Foreign Application Priority Data
Mar. 28, 2002 (JP) P.2002-092323

(51) Int. Cl. H05B 33/00

(52) U.S. Cl. 313/512

(57) ABSTRACT

An organic electroluminescent device comprising: a substrate; a cathode; at least one organic compound layer including a light-emitting layer; and a transparent anode, in this order, wherein a reducing-compound layer is located between the substrate and the cathode.

### FIELD OF THE INVENTION

This invention relates to a light-emitting device (LED) (electroluminescent device) which is effectively useful as, for example, a planar light source for full color displays, a planar backlight, a planar light source for illumination, and a light source array for printers. More particularly, it relates to an organic LED (organic electroluminescent device) excellent in luminance and durability.

### BACKGROUND OF THE INVENTION

Organic light-emitting devices (OLEDs) using organic substances are promising candidates for application to inexpensive, solid-state, full-color, wide flat-panel displays or writing light source arrays for printers and have been studied intensively and extensively. OLEDs are generally composed of a pair of opposing electrodes having sandwiched therebetween an organic light-emitting layer. Light emission (luminescence) is a phenomenon that, upon electric field application between the electrodes, electrons are injected from the cathode, and positive holes are injected from the anode, the injected electrons and holes are recombined in the light-emitting layer, and the energy level returns from the conduction band to the valence band while emitting energy as light output.

While conventional OLEDs have had disadvantages such as high driving voltage, low luminance, and low luminescence efficiency, various technologies have recently been reported addressing these problems. An OLED having an organic thin film formed by vacuum evaporation of an organic compound is among such technologies (see Applied Physics Letters, 1987, 51, 913). The organic layer of this device has a dual layer structure composed of an electron-transporting layer comprising an electron-transporting material and a hole-transporting layer comprising a hole-transporting material and achieves greatly improved luminescence characteristics compared with OLEDs having a single layer structure. The reported OLED uses a low molecular amine compound as a hole-transporting material and tris(8-hydroxyquinolinato)aluminum (Alq) as an electron-transporting material and a light-emitting material. It emits green light.

Since then a large number of reports have been made on OLEDs having vacuum-evaporated organic thin films (see references cited in Macromolecular Symposium, 1997, 125, 1).

Nevertheless these OLEDs still cannot get rid of the very low luminescence efficiency problem as compared with inorganic LEDs and fluorescent tubes. Most of the proposed OLEDs make use of fluorescent luminescence obtained from singlet excitons of an organic LE material. In a simple quantum chemical mechanism, the ratio of singlet excitons providing fluorescence to triplet excitons providing phosphorescence is theoretically 1:3. As long as fluorescence luminescence is used, only 25% of the excitons are made effective use of, only to achieve low luminescence efficiency. Utilization of phosphorescence provided by triplet excitons would bring about remarkable improvement on luminescence efficiency.

In recent years, OLEDs relying on phosphorescence from an iridium-phenylpyridine complex have been reported in Applied Physics Letter, 1999, 75, 4 and Japanese Journal of Applied Physics, 1999, 38, L1502. The reports note that the researchers have succeeded in obtaining 2 to 3 times as high luminescence efficiency as those obtained by conventional OLEDs using fluorescence. The levels reached in the reports, however, are lower than the theoretically reachable luminescence efficiency, still leaving room for further improvement. In addition, production of these OLEDs involves dry film formation processing, such as vacuum evaporation, of a low-molecular compound. As a result, there unavoidably occurs deterioration of the low-molecular compound due to crystallization. Also, dry film formation techniques incur high production cost and have poor productivity.

On the other hand, OLEDs produced by forming a polymer film in wet process have been proposed aiming at production cost reduction and application to large-area devices, such as backlights and light sources for illumination. Applicable polymers include poly-p-phenylene vinylene showing green light emission (Nature, 1990, 347, 539), poly(3-alkylthiophene) providing reddish orange luminescence (Japanese Journal of Applied Physics, 1991, 30, L1938), and polyalkylfluorene (Japanese Journal of Applied Physics, 1991, 30, L1941). JP-A-2-223188 discloses a wet process of film formation using a dispersion of a low-molecular compound in a binder resin. All these teachings on wet film formation techniques are confined to OLEDs utilizing fluorescence luminescence provided by singlet excitons. Therefore, the proposed OLEDs have low luminescence efficiency.

None of the state-of-the-art OLEDs is satisfactory in durability, either of wet-coated type or vacuum-evaporated type or either of singlet exciton luminescence type or triplet exciton luminescence type. One of the big bars to improvement on durability is a moisture problem. Moisture, if present in an OLED, is electrolytically decomposed into oxygen and hydrogen, which causes deterioration of durability. Besides the electrolytic decomposition, moisture reacts with the cathode, also causing deterioration of durability. It has been proposed to put a desiccant in a sealed OLED to remove moisture (see JP-A-9-148066). A desiccant is capable of removing moisture from the environment but incapable from the substrate or the organic compound layer. JP-A-2002-8852 proposes placing an alkali metal or an alkaline earth metal in a sealed space of an OLED. However, because these metals are so reactive with moisture or oxygen, they are unstable when set in a sealed space, failing to assure stable durability. Therefore, a method for thoroughly removing the water content from a device has keenly been demanded in this field.

It has been thought that the arrangement of an anode and a cathode is reversed. That is, a cathode is arranged on a substrate side, and emitted light is outputted from the opposite anode side. This structure will hereinafter be designated “reverse configuration”.

One of the advantages of the reverse configuration is a high aperture ratio (ratio of emissive portion per pixel). In an ordinary configuration, at least one or two thin film transistors (TFTs) made of α-Si, polysilicon, etc. are provided per pixel on a transparent substrate, and a large number of scanning electrode lines and signal electrode lines for selectively switching the TFTs on are provided on the substrate. In order to electrically isolate the TFT and OLED, an insulating film of silicon nitride, silicon oxide, etc. is formed on the TFTs.

Because the thickness of a TFT inclusive of gate, drain, and source electrodes is 0.2 to 1 μm to make a level difference, the lower electrode should be formed around the TFT, unavoidably generating a non-emissive area in a pixel. Where light is emitted from the transparent substrate side, the scanning electrode lines and the signal electrode lines also shut out light, further reducing the pixel aperture ratio. On the other hand, a device having the reverse configuration achieves a high aperture ratio because light is emitted from the side opposite to the substrate having TFTs.

Besides, in the absence of need to emit light from the substrate side, a non-transparent substrate can be used. In other words, freedom of design is broader in selecting the material of the substrate, enabling use of a flexible substrate, such as a polyimide film. Since cathode layer formation precedes organic layer formation, damage to the organic layer by ashing involved in cathode layer formation can be averted.

The above-mentioned durability problem is also outstanding for the reverse configuration device.

### SUMMARY OF THE INVENTION

In the light of these circumstances, an object of the present invention is to provide a reverse configuration type OLED excellent in durability and luminance which can find effective applications as a planar light source of full color displays, backlights, lighting equipment, etc. and as a light source array for printers, etc.

The object of the present invention is accomplished by a light-emitting device comprising a substrate having stacked thereon a cathode, at least one organic compound layer including at least a light-emitting layer, and a transparent anode in this order, which further has a reducing-compound layer containing a reducing compound between the substrate and the cathode.

The invention includes the following preferred embodiments.

The light-emitting device in which the reducing compound is a reducing metal oxide.

The light-emitting device in which the reducing metal oxide is at least one of SiO, GeO, SnO, and FeO.

The light-emitting device in which the reducing compound is a metal or a metal alloy each having a work function of 4.0 eV or less.

### BRIEF DESCRIPTION OF THE DRAWINGS

[FIG. 1]

FIG. 1 is a sketch of an OLED according to the present invention.

### DESCRIPTION OF REFERENCE NUMERALS

Numeral 1 indicates a substrate; 2, a reducing-compound layer; 3, a cathode; 4, an organic compound layer; 5, an anode; 6, a sealing layer; and 7, a stack of layers (layers comprising 2, 3, 4, and 5).

### DETAILED DESCRIPTION OF THE INVENTION

The OLED of the invention comprises a substrate having stacked thereon a cathode, at least one organic compound layer including at least a light-emitting layer, and a transparent anode in this order, wherein a reducing-compound layer containing a reducing compound is provided between the substrate and the cathode.

The reducing-compound layer is a layer capable of reacting with moisture at room temperature to generate hydrogen gas and also with oxygen at room temperature in the inner space of an OLED.

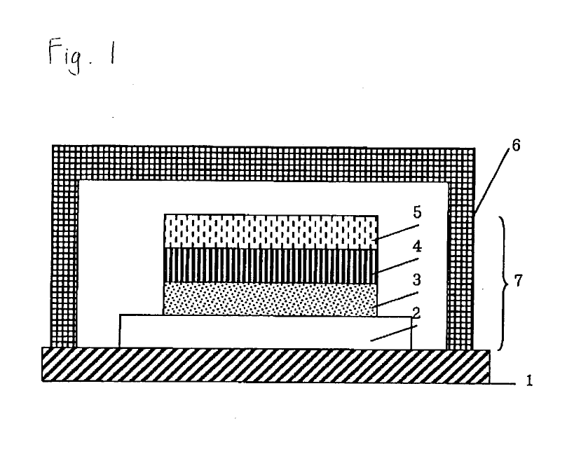

FIG. 1 is a sketch of an OLED according to the present invention. In FIG. 1, numeral 1 indicates a substrate; 2, a reducing-compound layer; 3, a cathode; 4, an organic compound layer; 5, a transparent anode; and 6, a sealing member. The stack of layers 2, 3, 4, and 5 is shut off the outside, being sealed by the substrate 1 and the sealing layer (member) 6 in an inert gas (e.g., nitrogen or argon) atmosphere.

The reducing-compound layer 2 is provided between the substrate and the cathode. Moisture contained in the substrate is efficiently absorbed by this layer without being allowed to react on the cathode. This eventually enables stable handling of active alkali metals or alkaline earth metals.

Reducing compounds are used to make up the reducing-compound layer. Useful reducing compounds include metal oxides having an oxidation state lower than the maximum oxygen number, metal nitrides, metal halides, metals or alloys whose work function is smaller than 4.0 eV (preferably smaller than 3.7 eV), and organic compounds whose ionization potential is smaller than 5.0 eV. From the standpoint of ease of handling and availability, preferred of them are reducing metal oxides whose oxidation state is lower than the maximum oxygen number and metals or alloys whose work function is smaller than 4.0 eV. The metals of the metal oxides are elements of from groups IIIA to VIB and from the 4^{th} to 6^{th} periods in the long form of the periodic table, Al, Si, and P.

Preferred reducing metal oxides are SiO, GeO, SnO, FeO, MnO, and WO, with SiO, GeO, SnO, and FeO being particularly preferred.

The metals or alloys having a work function smaller than 4.0 eV include Ca, Ce, Cs, Er, Eu, Gd, Hf, K, La, Li, Mg, Nd, Rb, Sc, Sm, Y, Yb, and Zn, and their alloys. From the viewpoint of availability and ease of handling, at least one metal selected from Ca, Li, and Mg or an alloy thereof is particularly preferred.

The reducing-compound layer is not particularly limited by method of formation. Vacuum evaporation or sputtering is recommended. It is advisable to adopt the same film formation method for the reducing-compound layer and the cathode so that formation of the two layers may be carried out in succession, which contributes to process simplification.

The reducing-compound layer served as at least one moisture-and oxygen-absorbing layer to reduce at least one moisture and oxygen inside of the device. The reducing-compound layer is located between the substrate and the cathode, whereby the penetration of at least one moisture and oxygen through the substrate is reduced effectively.

The thickness of the reducing-compound layer is not particularly limited as long as the layer can hold a sufficient amount of a moisture- and oxygen-absorbing agent for absorbing moisture and oxygen to a satisfactory degree. The thickness is preferably 10 nm to 1 μm, still preferably 50 to 500 nm. A thinner layer than 10 nm tends to have an insufficient moisture-absorbing capacity. A thicker layer than 1 μm needs an unfavorably long time for film formation and tends to separate from the substrate or the cathode.

The OLED of the invention will be described below in detail.

Materials of the substrate include inorganic substances, such as yttrium-stabilized zirconia (YSZ) and glass, and organic substances, such as polyesters, e.g., polyethylene terephthalate, polybutylene phthalate, and polyethylene naphthalate, polystyrene, polycarbonate, polyether sulfone, polyarylate, polyimide, polycycloolefins, norbornene resins, polychlorotrifluoroethylene, and polyimide. In using an organic material, it is advisable to select one excellent in heat resistance, dimensional stability, solvent resistance, electrical insulating properties, and processability.

The shape, structure, and size of the substrate are not particularly limited and selected appropriately according to the intended use or purpose of the device. In general, the substrate has a plate shape and may have either a single layer structure or a multilayer structure. It may be made of a single member or two or more members.

The substrate may be either colorless and transparent or opaque.

The substrate may have a moisture barrier layer (or a gas barrier layer) formed on either side thereof. Suitable materials for making the moisture barrier layer include inorganic substances such as silicon nitride and silicon oxide. The moisture barrier layer can be formed by, for example, RF sputtering.

If desired, the substrate may further have a hard coat layer, an undercoat layer, etc. formed thereon.

The cathode is usually not limited in shape, structure and size as long as the function of injecting electrons into the organic compound layer is fulfilled. The shape, structure, and size are appropriately chosen from known electrode designs according to the intended use or purpose of the device.

Materials making up the cathode include metals, alloys, metal oxides, electrically conductive compounds, and mixtures thereof. Those having a work function of 4.5 eV or less are preferred. Examples of such materials are alkali metals (e.g., Li, Na, K, and Cs), alkaline earth metals (e.g., Mg and Ca), gold, silver, lead, aluminum, sodium-potassium alloys, lithium-aluminum alloys, magnesium-silver alloys, and rare earth metals (e.g., indium and ytterbium). These materials can be used individually or as a combination of two or more thereof. A combined use is preferred for obtaining both stability and electron injection properties.

Alkali metals and alkaline earth metals are preferred from the aspect of electron injection, and aluminum-based materials are preferred from the aspect of storage stability.

The aluminum-based materials include aluminum and mixtures or alloys comprising aluminum and 0.01 to 10% by weight of an alkali metal or an alkaline earth metal, such as an Al—Li alloy and an Al-Mg alloy.

For more detailed information about the cathode materials, refer to JP-A-2-15595 and JP-A-5-121172.

The cathode can be formed by any known method with no particular restriction. It is preferred in the invention to form the cathode by vacuum thin film formation techniques. A suitable process is selected from physical vapor deposition (PVD) processes, such as vacuum evaporation, sputtering, and ion plating, and chemical vapor deposition (CVD) processes including plasma-enhanced CVD, taking suitability of the material into consideration. For instance, in using metals as cathode materials, the cathode can be formed by sputtering one or more metal materials simultaneously or successively.

Methods of patterning the cathode layer include chemical etching by photolithography and like techniques and physical etching with a laser beam, etc. Otherwise, the cathode can be formed patternwise by vacuum evaporation, sputtering or a like thin film formation technique through a pattern mask, or by a lift-off method or a printing method.

A dielectric layer made of, for example, a fluoride of the above-recited alkali metal or alkaline earth metal may be formed between the cathode and the organic compound layer to a thickness of 0.1 to 5 nm. The dielectric layer can be formed by, for example, vacuum evaporation, sputtering or ion plating.

The thickness of the cathode is subject to variation depending on the material and cannot be generally specified. A usual thickness is 10 nm to 5 μm, preferably 50 nm to 1 μm.

The organic compound layer comprises one or more organic compound layers one of which is a light-emitting layer. Examples of the organic compound layer structure in combination with the anode and the cathode include (1) transparent anode/light-emitting layer/cathode, (2) transparent anode/light-emitting layer/electron-transporting layer/cathode, transparent anode/hole-transporting layer/light-emitting layer/electron-transporting layer/cathode, transparent anode/hole-transporting layer/light-emitting layer/cathode, transparent anode/light-emitting layer/electron-transporting layer/electron-injecting layer/cathode, and transparent anode/hole-injecting layer/hole-transporting layer/light-emitting layer/electron-transporting layer/ele ctron-injecting layer/cathode.

The light-emitting layer comprises at least one light-emitting material. If desired, the light-emitting layer can contain a hole-transporting material, an electron-transporting material, and a host material.

The light-emitting material which can be used in the invention is not particularly limited, and any fluorescent compounds and phosphorescent compounds can be employed. Examples of fluorescent compounds include benzoxazole derivatives (the term “derivative(s)” is used to mean not only derivatives of a compound indicated but also the compound per se, hereinafter the same), benzimidazole derivatives, benzothiazole derivatives, styrylbenzene derivatives, polyphenyl derivatives, diphenylbutadiene derivatives, tetraphenylbutadiene derivatives, naphthylimide derivatives, coumarin derivatives, perylene derivatives, perinone derivatives, oxadiazole derivatives, aldazine derivatives, pyrralidine derivatives, cyclopentadiene derivatives, bisstyrylanthracene derivatives, quinacridone derivatives, pyrrolopyridine derivatives, thiadiazolopyridine derivatives, styrylamine derivatives, aromatic dimethylidyne compounds; various metal complexes typified by metal complexes or rare earth element complexes of 8-quinolinol derivatives; and polymers, such as polythiophene derivatives, polyphenylene derivatives, polyphenylene vinylene derivatives, and polyfluorene derivatives. These fluorescent compounds can be used either individually or as a mixture of two or more thereof.

The phosphorescent materials preferably include, but are not limited to, ortho-metalated complexes and porphyrin metal complexes.

“Ortho-metalated complex” is a generic term given to the compounds described, e.g., in Yamamoto Akio, Yukikinzokukagaku-kiso to ohyo, Shokabo Publishing Co., 1982, p150 and 232 and H. Yersin, Photochemistry and Photophysics of Coordination Compounds, Springer-Verlag, 1987, pp. 71-77 and 135-146. The organic compound layer containing the ortho-metalated complex is advantageous in terms of luminance and luminescence efficiency.

There are various ligands which form the ortho-metalated complexes, including those described in the literature cited above. Preferred of them include 2-phenylpyridine derivatives, 7,8-benzoquinoline derivatives, 2-(2-thienyl)pyridine derivatives, 2-(1-naphthyl)pyridine derivatives, and 2-phenylquinoline derivatives. These derivatives may have a substituent according to necessity. The ortho-metalated complexes can have other ligands in addition to the above-recited ones.

The ortho-metalated complexes which can be used in the invention are synthesized according to various known techniques, such as those described in Inorg. Chem., 1991, 30, 1685, ibid., 1988, 27, 3464, ibid., 1994, 33, 545, Inorg. Chim. Acta, 1991, 181, 245, J. Organomet. Chem., 1987, 335, 293, and J. Am. Chem. Soc., 1985, 107, 1431.

Of the ortho-metalated complexes those emitting light from triplet excitons are preferred for luminescence efficiency.

Of the porphyrin metal complexes preferred are porphyrin platinum complexes.

The phosphorescent compounds can be used either individually or as a combination of two or more thereof. The fluorescent compounds and the phosphorescent compounds can be used in combination. From the standpoint of emission luminance and efficiency, the phosphorescent compounds are preferred.

The hole-transporting materials which can be used in the invention are not limited, whether low-molecular or high-molecular, as long as any one of a function of injecting holes from the anode, a function of transporting the holes, and a function of blocking the electrons injected from the cathode is performed. Examples of such materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, polysilane compounds, poly(N-vinylcarbazole) derivatives, aniline copolymers; conductive oligomers, such as thiophene oligomers and polythiophene; and polymers, such as polythiophene derivatives, polyphenylene derivatives, polyphenylene vinylene derivatives, and polyfluorene derivatives. They can be used either individually or as a combination of two or more thereof.

The light-emitting layer can contain the hole-transporting material in an amount of 0 to 99.9% by weight, preferably 0 to 80% by weight.

The electron-transporting material which can be used in the invention are not limited as long as a function of transporting electrons or a function of blocking the holes injected from the anode is performed. Examples of electron-transporting materials include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiiumide derivatives, fluorenylidenemethane derivatives, distyrylpyrazine derivatives, heterocyclic (e.g., naphthalene or perylene) tetracarboxylic acid anhydrides, phthalocyanine derivatives, various metal complexes, such as metal complexes of 8-quinoliol derivatives, metallo-phthalocyanines, and metal complexes having benzoxazole or benzothiazole as a ligand, aniline copolymers, conductive oligomers, such as thiophene oligomers and polythiophene, and polymers, such as polythiophene derivatives, polyphenylene derivatives, polyphenylene vinylene derivatives, and polyfluorene derivatives. The light-emitting layer preferably contains the electron-transporting material in an amount of 0 to 99.9% by weight, particularly 0 to 80% by weight.

The host material is a compound capable of transferring energy of its excited state to the fluorescent or phosphorescent compound to cause the fluorescent or phosphorescent compound to emit light.

The host material can be selected appropriately according to the purpose from among any compounds capable of transferring its excitons' energy to a light-emitting material. Examples of suitable host materials include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stilbene derivatives, silazane derivatives, aromatic tertiary amine compounds, styrylamine compounds, aromatic dimethylidyne compounds, porphyrin compounds, anthraquinodimethane derivatives, anthrone derivatives, diphenylquinone derivatives, thiopyran dioxide derivatives, carbodiimide derivatives, fluorenylidenemethane derivatives, distrylpyrazine derivatives, heterocyclic (e.g., naphthalene or perylene) tetracarboxylic acid anhydrides, phthalocyanine derivatives, various metal complexes, such as metal complexes of 8-quinoliol derivatives, metallo-phthalocyanines, and metal complexes having benzoxazole or benzothiazole as a ligand, polysilane compounds, poly(N-vinylcarbazole) derivatives, aniline copolymers, conductive oligomers, such as thiophene oligomers and polythiophene, and polymers, such as polythiophene derivatives, polyphenylene derivatives, polyphenylene vinylene derivatives, and polyfluorene derivatives.

The host materials can be used either individually or as a combination of two or more thereof. The light-emitting layer preferably contains 0 to 99.9% by weight, particularly 0 to 99.0% by weight, of the host material.

The other components the light-emitting layer can contain according to necessity include electrically inert binder resins. Examples of useful binder resins are polyvinyl chloride, polycarbonate, polystyrene, polymethyl methacrylate, polybutyl methacrylate, polyester, polysulfone, polyphenylene oxide, polybutadiene, hydrocarbon resins, ketone resins, phenoxy resins, polyamide, ethyl cellulose, polyvinyl acetate, ABS resins, polyurethane, melamine resins, unsaturated polyester resins, alkyd resins, epoxy resins, silicone resins, polyvinyl butyral, and polyvinyl acetal.

Use of the binder is advantageous in that the light-emitting layer can be formed easily and over a wide area by a wet film formation technique.

If desired, the OLED of the invention may contain other organic compound layers in addition to the light-emitting layer. For example, a hole-injecting layer or a hole-transporting layer may be provided between the transparent anode and the light-emitting layer and/or an electron-transporting layer or an electron-injecting layer may be provided between the light-emitting layer and the cathode.

The hole-transporting layer and the hole-injecting layer are suitably made of the hole-transporting material, and the electron-transporting layer and the electron-injecting layer are suitably made of the electron-transporting material.

The organic compound layers, including the light-emitting layer and others, can be formed by dry film formation techniques (dry process), such as vacuum evaporation and sputtering, and wet film formation techniques (wet process), such as dipping, spin coating, dip coating, casting, die coating, roll coating, bar coating, and gravure coating.

A suitable film formation technique is chosen according to the material of the layer. The wet processes are advantageous in that the organic compound layer can be formed over a wide area easily to efficiently provide an OLED with high luminance and luminescence efficiency at low cost. A layer formed by a wet process may be dried. The drying conditions, while not particularly limited, should be selected so as not to damage the layer.

As previously stated, a binder resin can be incorporated into an organic compound layer where the layer is to be formed by the wet process. Examples of useful binder resins which can be used in the organic compound layers are the same as those recited above with respect to the light-emitting layer. The binder resins can be used either individually or as a mixture thereof in each layer.

Where the organic compound layer is to be formed by the wet process, a coating composition is prepared by dissolving the organic material in a solvent. The solvent to be used is not particularly limited and chosen appropriately according to the kinds of the constituents, i.e., the hole-transporting material, the ortho-metalated complex, the host material, the binder resin, and so forth. Examples of useful solvents are halogen-containing solvents, such as chloroform, carbon tetrachloride, dichloromethane, 1,2-dichloroethane, and chlorobenzene; ketones, such as acetone, methyl ethyl ketone, diethyl ketone, n-propyl methyl ketone, and cyclohexanone; aromaticsolvents, suchasbenzene, toluene, and xylene; esters, such as ethyl acetate, n-propyl acetate, n-butyl acetate, methyl propionate, ethyl propionate, γ-butyrolactone, and diethyl carbonate; ethers, such as tetrahydrofuran and dioxane; amide solvents, such as dimethylformamide and dimethylacetamide; dimethyl sulfoxide; and water.

The ratio of the solvent to the solids content in the coating composition is not particularly limited. The density of the coating composition is also arbitrarily selected depending on the wet process adopted.

The transparent anode is, generally, not limited in shape, structure, size, etc. as long as the function as an anode (to supply positive holes to the organic compound layer) is fulfilled. The transparent anode is selected appropriately from among known electrodes according to the use and purpose of the light-emitting device.

Suitable materials of the transparent anode include metals, alloys, metal oxides, organic conductive compounds, and mixtures thereof. Those having a work function of 4.0 eV or more are preferred. Such materials include semiconductive metal oxides, such as tin oxide doped with antimony, fluorine, etc. (e.g., ATO or FTO), tin oxide, zinc oxide, indium oxide, indium tin oxide (ITO), and indium zinc oxide (IZO); metals, such as gold, silver, chromium, and nickel; mixtures or composite laminates composed of these metals and conductive metal oxides; inorganic conductive substances, such as copper iodide and copper sulfide; dispersions of the semiconductive metal oxides or metal compounds; organic conductive materials, such as polyaniline, polythiophene, and polypyrrole; and composite laminates composed of these materials and ITO.

The transparent anode can be formed on the organic compound layer by a process properly selected according to suitability to the material from among PVD processes, such as vacuum evaporation, sputtering, and ion plating, and CVD processes including plasma-enhanced CVD. For instance, an ITO film can be formed by DC sputtering, RF sputtering, vacuum evaporation, or ion plating.

Methods of patterning the anode layer include chemical etching by photolithography or like techniques and physical etching with a laser beam, etc. Otherwise, the anode can be formed patternwise by vacuum evaporation, sputtering or a like dry film formation process through a pattern mask, or by a lift-off method or a printing method.

The thickness of the anode cannot be generally specified, being subject to variation depending on the material. A usual thickness is 10 nm to 50 μm, preferably 50 nm to 20 μm. The transparent anode preferably has a resistivity of 10⁶ Ω/sq. or less, particularly 10⁵ Ω/sq. or less. With a resistivity of 10⁵ Ω/sq. or less, a wide-area LED having excellent performance can be obtained by laying the bus line electrodes according to the present invention.

The transparent anode may be either colorless or colored. In order to obtain light output from the anode side, the transmission of the transparent anode is preferably 60% or higher, still preferably 70% or higher. The transmission is measured with a spectrophotometer in a known manner.

The OLED of the invention can comprise other layers according to the purpose, for example, a protective layer. Suitable examples of the protective layer are described in JP-A-7-85974, JP-A-7-192866, JP-A-8-22891, JP-A-10-275682, and JP-A-10-106746. The shape, size, thickness, etc. of the protective layer are decided appropriately. The protective layer can be of any material that prevents substances which may accelerate deterioration of the device, such as moisture and oxygen, from entering or penetrating the device. Such materials include silicon oxide, silicon dioxide, germanium oxide, and germanium dioxide.

Methods for forming the protective layer include, but are not limited to, vacuum evaporation, sputtering, reactive sputtering, molecular beam epitaxial growth, cluster ion beam-assisted deposition, ion plating, plasma polymerization, plasma-enhanced CVD, laser-assisted CVD, thermal CVD, and wet coating processes.

A sealing layer is also a preferred layer to be provided for preventing moisture and oxygen from entering the constituent layers of the device. Materials of the sealing layer include tetrafluoroethylene copolymers, fluorine-containing copolymers having a cyclic structure in the main chain, polyethylene, polypropylene, polymethyl methacrylate, polyimide, polyurea, polytetrafluoroethylene, polychlorotrifluoroethylene, polydichlorodifluoroethylene, copolymers comprising at least one unit selected from chlorotrifluoroethylene and dichlorodifluoroethylene, water-absorbing substances having a water absorption of at least 1%, moisture-proof substances having a water absorption of 0.1% or less, metals, e.g., In, Sn, Pb, Au, Cu, Ag, Al, Tl, and Ni, metal oxides, e.g., MgO, SiO, SiO₂, Al₂O₃, GeO, NiO, CaO, BaO, Fe₂O₃, Y₂O₃, and TiO₂, metal fluorides, e.g., MgF₂, LiF, AlF₃, and CaF₂, liquid fluorocarbons, e.g., perfluoroalkanes, perfluoroamines, and perfluoroethers, and dispersions of moisture/oxygen-adsorbing substances in a liquid fluorocarbon.

A moisture absorber or an inert liquid may be disposed in the space between the container (sealing member) and the device. The moisture absorber includes, but is not limited to, barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadiumbromide, molecular sieve, zeolite, and magnesium oxide. The inert liquid includes, but is not limited to, paraffins, liquid paraffins, fluorine-containing solvents, such as perfluoroalkanes, perfluoroamines, and perfluoroethers, chlorine-containing solvents, and silicone oils.

The OLED of the invention emits light on applying a DC (which may contain, if desired, an alternating component) voltage (usually 2 to 40 V) or a DC current between the anode and the cathode. For driving the OLED of the invention, the methods described in JP-A-2-148687, JP-A-6-301355, JP-A-5-29080, JP-A-7-134558, JP-A-8-234685, JP-A-8-241047, U.S. Pat. Nos. 5,828,429 and 6,0233,308, and Japanese Patent 2784615 can be made use of.

### EXAMPLES

The present invention will now be illustrated in greater detail with reference to Examples, but it should be understood that the invention is not deemed to be limited thereto.

### Example 1

A 2.5 cm side square cut out of a 0.2 mm thick polyester film (Teijin Tetron Film O, available from Teijin Ltd.) was used as a substrate. SiO was deposited on the substrate by vacuum evaporation to a deposit thickness of 50 nm to form a reducing-compound layer.

Aluminum and then LiF were successively deposited thereon by vacuum evaporation to a thickness of 250 nm and 3 nm, respectively, to form a cathode and an electron-injecting layer, respectively.

On the electron-injecting layer was deposited 2,2′,2″-(1,3,5-benzenetriyl)tris[3-(2-methylphenyl)-3H-imi dazo [4,5-b]pyridine] by vacuum evaporation at a deposition rate of 1 nm/sec to form a 0.024 μm thick electron-transporting layer.

Tris(2-phenylpyridyl)iridium as a phosphorescent ortho-metalated complex and 4,4′-N,N′-dicarbazolebiphenyl as a host material were co-deposited by vacuum evaporation at a deposition rate of 0.1 nm/sec and 1 nm/sec, respectively, to form a 0.024 μm thick light-emitting layer.

On the light-emitting layer was deposited N,N′-dinaphthyl-N,N′-diphenylbenzidine by vacuum evaporation at a rate of 1 nm/sec to form a 0.04 μm thick hole-transporting layer.

An ITO thin film (thickness: 0.2 μm) was formed as a transparent anode on the hole-transporting layer by DC magnetron sputtering using an ITO target having an In₂O₃ content of 95% by weight at a substrate temperature of 100° C. under an oxygen partial pressure of 1×10⁻3 Pa. An aluminum lead was connected to each of the anode and the cathode. The resulting stack of layers was put in a glove box purged with nitrogen and sealed into a glass container with a UV-curing adhesive (XNR 5493T, available from Nagese-CIBA Ltd.) to complete an OLED.

The resulting OLED was evaluated as follows. A DC voltage was applied to the OLED by use of Source-Measure Unit Model 2400 supplied by Toyo Corp., and the maximum luminance Lₘₐₓ and the voltage for obtaining the Lₘₐₓ were recorded. The luminescence efficiency at 200 cd/m² (η₂₀₀) was obtained. These results are shown in Table 1 below in the row “initial”. To evaluate durability, the OLED was left to stand at 85° C. and 95% RH for 30 days, and the luminescence performance was measured in the same manner as described above. The Lₘₐₓ, Vₘₐₓ, and η₂₀₀ thus obtained are shown in Table 1 in the row “After 30 Days”.

### Example 2

An OLED was prepared and evaluated in the same manner as in Example 1, except for replacing SiO used as a moisture- and oxygen-absorbing material with GeO. The results of evaluation are shown in Table 1.

### Example 3

An OLED was prepared and evaluated in the same manner as in Example 1, except for replacing SiO used as a moisture- and oxygen-absorbing material with SnO. The results of evaluation are shown in Table 1.

### Example 4

An OLED was prepared and evaluated in the same manner as in Example 1, except for replacing SiO used as a moisture- and oxygen-absorbing material with FeO. The results of evaluation are shown in Table 1.

### Example 5

An OLED was prepared and evaluated in the same manner as in Example 1, except for replacing SiO used as a moisture- and oxygen-absorbing material with Ca (work function: 3.0 eV). The results of evaluation are shown in Table 1.

### Example 6

An OLED was prepared and evaluated in the same manner as in Example 1, except for replacing SiO used as a moisture- and oxygen-absorbing material with Li (work function: 2.9 eV). The results of evaluation are shown in Table 1.

### Comparative Example 1

An OLED was prepared and evaluated in the same manner as in Example 1, except that the reducing-compound layer was not provided. The results of evaluation are shown in Table 1. It is seen that the device had more dark spots, lower external quantum efficiency, and poorer durability than those of Examples.

TABLE 1

| | | Lₘₐₓ | Vₘₐₓ | η₂₀₀ |
|---|---|---|---|---|
| Example 1 | initial | 82000 | 13 | 16.7 |
| | after 30 days | 76000 | 13 | 16.0 |
| Example 2 | initial | 80000 | 13 | 16.1 |
| | after 30 days | 75000 | 13 | 15.0 |
| Example 3 | initial | 78000 | 13 | 16.2 |
| | after 30 days | 74000 | 13 | 15.0 |
| Example 4 | initial | 78000 | 13 | 16.0 |
| | after 30 days | 72000 | 13 | 15.0 |
| Example 5 | initial | 81000 | 13 | 16.2 |
| | after 30 days | 73000 | 13 | 15.4 |
| Example 6 | initial | 80000 | 13 | 16.5 |
| | after 30 days | 71000 | 13 | 15.2 |
| Comparative | initial | 80000 | 13 | 16.0 |
| Example 1 | after 30 days | 7800 | 20 | 5.7 |

The present invention succeeded in settling the outstanding problems associated with conventional OLEDs. The present invention provides an OLED which exhibits high luminance, high luminescence efficiency, and, particularly excellent durability and finds effective use as a planar light source of full color displays, backlights, lighting equipment, and the like.

This application is based on Japanese Patent application JP 2002-92323, filed Mar. 28, 2002, the entire content of which is hereby incorporated by reference, the same as if set forth at length.

What is claimed is:

1. An organic electroluminescent device comprising:
a substrate;
a cathode;
at least one organic compound layer including a light-emitting layer; and
a transparent anode, in this order,
wherein a reducing-compound layer is located between the substrate and the cathode.

2. The organic electroluminescent device of claim 1, wherein the reducing-compound layer comprises a reducing metal oxide.

3. The organic electroluminescent device of claim 2, wherein the reducing metal oxide is at least one compound selected from the group consisting of SiO, GeO, SnO, and FeO.

4. The organic electroluminescent device of claim 1, wherein the reducing-compound layer comprises at least one metal and metal alloy each having a work function of 4.0 eV or less.

5. The organic electroluminescent device of claim 4, wherein the at least one metal and metal alloy is selected from the group consisting of Ca, Ce, Cs, Er, Eu, Gd, Hf, K, La, Li, Mg, Nd, Rb, Sc, Sm, Y, Yb, and Zn, and their alloys.

6. The organic electroluminescent device of claim 4, wherein the at least one metal and metal alloy is selected from the group consisting of Ca, Li, and Mg, and their alloys.

7. The organic electroluminescent device of claim 1, wherein the reducing-compound layer comprises a reducing metal oxide whose oxidation state is lower than a maximum oxygen number.

8. The organic electroluminescent device of claim 7, wherein the reducing metal oxide is SiO, GeO, SnO, FeO, MnO, or WO.

9. The organic electroluminescent device of claim 7, wherein the reducing metal oxide is SiO, GeO, SnO, or FeO.

10. The organic electroluminescent device of claim 1, wherein the reducing-compound layer has a thickness of from 10 nm to 1 μm.

11. The organic electroluminescent device of claim 1, wherein the reducing-compound layer has a thickness of from 50 nm to 500 nm.

12. The organic electroluminescent device of claim 1, wherein the transparent anode has a resistivity of 10⁶ Ω/square or less.

13. The organic electroluminescent device of claim 1, wherein the transparent anode has a transmission of 60% or higher.

14. The organic electroluminescent device of claim 1, further comprising a dielectric layer between the cathode and the organic compound layer.

15. The organic electroluminescent device of claim 1, further comprising a protective layer.

16. The organic electroluminescent device of claim 1, further comprising a sealing layer.

17. The organic electroluminescent device of claim 1, wherein the reducing-compound layer serves as at least one moisture- and oxygen- absorbing layer.

18. The organic electroluminescent device of claim 1, wherein an area of the reducing-compound layer is the approximately same or larger than the cathode.

19. The organic electroluminescent device of claim 16, wherein a void between the sealing layer (6) and a stack of layers (7) is purged with nitrogen gas.
